(19) United States
(12) Patent Application Publication
(10) Pub. No.: US 2024/0413125 A1
(43) Pub. Date: Dec. 12, 2024

(54) SEMICONDUCTOR PACKAGE

(71) Applicant: SAMSUNG ELECTRONICS CO., LTD., Suwon-si (KR)

(72) Inventors: Seho You, Suwon-si (KR); Sangcheon Park, Suwon-si (KR)

(21) Appl. No.: 18/677,392

(22) Filed: May 29, 2024

(30) Foreign Application Priority Data
Jun. 12, 2023 (KR) 10-2023-0075068

(51) Int. Cl. H01L 25/065; G02B 6/42; H01L 23/00; H01L 23/498; H01L 23/538; H01L 25/07

(52) U.S. Cl. CPC H01L 25/0657; G02B 6/4202; H01L 23/49838; H01L 23/5386; H01L 24/05; H01L 24/08; H01L 24/16; H01L 25/071; H01L 2224/05013; H01L 2224/05573; H01L 2224/05687; H01L 2224/05688; H01L 2224/08145; H01L 2224/08235; H01L 2224/16227; H01L 2224/16238; H01L 2225/06517; H01L 2225/0652; H01L 2225/06548; H01L 2225/06562; H01L 2924/152

(57) ABSTRACT

Provided is a semiconductor package including a package substrate, a connection substrate mounted on the package substrate, and including a first conductive connection structure, a first integrated circuit device mounted on the package substrate, and a second integrated circuit device disposed on the connection substrate and the first integrated circuit device, and including a first portion overlapping the first integrated circuit device and a second portion overlapping the connection substrate, wherein one of the first integrated circuit device and the second integrated circuit device includes a photonic integrated circuit device to which an optical fiber is attached, and the other of the first integrated circuit device and the second integrated circuit device includes an electronic integrated circuit device, and wherein the second integrated circuit device is electrically connected to the package substrate via the first conductive connection structure of the connection substrate.

### CROSS-REFERENCE TO RELATED APPLICATION

This application is based on and claims priority under 35 U.S.C. § 119 to Korean Patent Application No. 10-2023-0075068, filed on Jun. 12, 2023 in the Korean Intellectual Property office, the disclosure of which is incorporated by reference herein in its entirety.

### BACKGROUND

With the rapid development of the electronics industry, electrical devices are required to have a higher data transmission speed. Recently, attempts have been made to apply photonic devices to electrical devices to implement high data transmission speeds. For example, various studies on co-packaged optics (CPO) packages including photonic integrated circuit (PIC) devices and electronic integrated circuit (EIC) devices, are being conducted to meet the demand for increasing communication speed and reducing signal loss.

### SUMMARY

This disclosure provides a semiconductor package including an electronic integrated circuit device and a photonic integrated circuit device.

According to an aspect of the disclosure, there is provided a semiconductor package including a package substrate, a connection substrate mounted on the package substrate, and including a first conductive connection structure, a first integrated circuit device mounted on the package substrate, and a second integrated circuit device disposed on the connection substrate and the first integrated circuit device, and including a first portion overlapping the first integrated circuit device and a second portion overlapping the connection substrate, wherein one of the first integrated circuit device and the second integrated circuit device includes a photonic integrated circuit device to which an optical fiber is attached, and the other of the first integrated circuit device and the second integrated circuit device includes an electronic integrated circuit device, and wherein the second integrated circuit device is electrically connected to the package substrate via the first conductive connection structure of the connection substrate.

According to another aspect of the disclosure, there is provided a semiconductor package including a package substrate, a connection substrate mounted on the package substrate, and including a mold-based base layer and a plurality of mold through electrodes penetrating the mold-based base layer, a photonic integrated circuit device mounted on the package substrate, and configured to transceive optical signals via an optical fiber, and an electronic integrated circuit device mounted on the photonic integrated circuit device and the connection substrate, and configured to process a signal provided by the photonic integrated circuit device, wherein the electronic integrated circuit device is directly connected to the photonic integrated circuit device and the connection substrate, and the electronic integrated circuit device is electrically connected to the package substrate via the plurality of mold through electrodes.

According to another aspect of the disclosure, there is provided a semiconductor package including a package substrate, a connection substrate mounted on the package substrate, a first integrated circuit device mounted on the package substrate, a second integrated circuit device disposed on the connection substrate and the first integrated circuit device, the second integrated circuit device directly connected to the first integrated circuit device, and electrically connected to the package substrate via the connection substrate, and a third integrated circuit device mounted on the connection substrate, and electrically connected to the second integrated circuit device via the connection substrate, wherein one of the first integrated circuit device and the second integrated circuit device includes a photonic integrated circuit device to which an optical fiber is attached, and the other of the first integrated circuit device and the second integrated circuit device includes an electronic integrated circuit device.

According to another aspect of the disclosure, there is provided a semiconductor package including a package substrate, an electronic integrated circuit device mounted on the package substrate, and including a plurality of through electrodes, and a photonic integrated circuit device directly connected to the electronic integrated circuit device, the photonic integrated circuit device electrically connected to the plurality of through electrodes, and including a photonic device attached thereto.

### BRIEF DESCRIPTION OF THE DRAWINGS

Implementations will be more clearly understood from the following detailed description taken in conjunction with the accompanying drawings in which:

FIG. 1 is a cross-sectional view of a semiconductor package according to some implementations;

FIG. 2 is a plan view of a first integrated circuit device and a connection substrate of a semiconductor package, according to some implementations;

FIG. 3 is a plan view of a first integrated circuit device and a connection substrate of a semiconductor package, according to some implementations;

FIG. 4 is an enlarged diagram of a junction region between a first integrated circuit device and a second integrated circuit device in a semiconductor package, according to some implementations;

FIG. 5 is an enlarged diagram of a junction region between the connection substrate and the second integrated circuit device in a semiconductor package, according to some implementations;

FIG. 6 is a cross-sectional view of a semiconductor package according to some implementations;

FIG. 7 is a cross-sectional view of a semiconductor package according to some implementations;

FIG. 8 is a cross-sectional view of a semiconductor package according to some implementations;

FIG. 9 is a cross-sectional view of a semiconductor package according to some implementations;

FIG. 10 is a cross-sectional view of a semiconductor package according to some implementations;

FIGS. 11A through 11E are diagrams for explaining a method of manufacturing a semiconductor package, according to some implementations; and

FIGS. 12A and 12B are cross-sectional views illustrating a method of manufacturing a semiconductor package, according to some implementations.

### DETAILED DESCRIPTION

Hereinafter, implementations of the disclosure are described in detail with reference to the accompanying drawings. Identical reference numerals are used for the same constituent elements in the drawings, and duplicate descriptions thereof are omitted.

In the disclosure, a vertical direction may be defined as a Z direction, and a horizontal direction may be defined as a direction perpendicular to the Z direction. A first horizontal direction and a second horizontal direction may be defined as directions crossing each other. The first horizontal direction may be referred to as an X direction, and the second horizontal direction may be referred to as a Y direction. A horizontal width of a component may be referred to as the length thereof in the horizontal direction, and a vertical level of a component may be referred to as a position in the vertical direction.

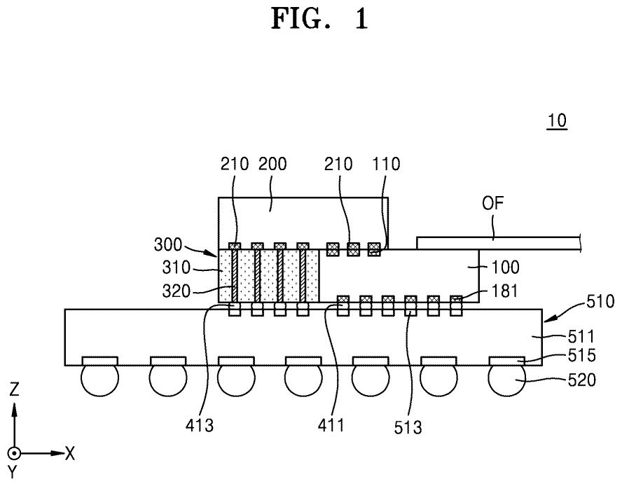

FIG. 1 is a cross-sectional view of a semiconductor package 10 according to some implementations.

Referring to FIG. 1, the semiconductor package 10 includes a package substrate 510, a first integrated circuit device 100, a second integrated circuit device 200, and a connection substrate 300.

The semiconductor package 10 may include a photonic integrated circuit (PIC) device configured to transceive and process optical signals and an electronic integrated circuit (EIC) device configured to process signals provided by the PIC device. The semiconductor package 10 may include a co-packaged optics (CPO) package in which the PIC device and the EIC device are packaged together. Any one of the first integrated circuit device 100 and the second integrated circuit device 200 may include a PIC device, and the other may include an EIC device.

The package substrate 510 may include, for example, a printed circuit board (PCB), a flexible substrate, or a tape substrate. The package substrate 510 includes a substrate base 511, a plurality of substrate upper pads 513 provided in an upper surface of the substrate base 511, and a plurality of substrate lower pads 515 provided in a lower surface of the substrate base 511. The substrate base 511 may include at least one material of phenol resin, epoxy resin, and polyimide. Each substrate upper pad 513 and each substrate lower pad 515 may include a conductive material, for example, copper. An external connection terminal 520 may be attached to each of the plurality of substrate lower pads 515.

The first integrated circuit device 100 may be mounted on the package substrate 510. For example, the first integrated circuit device 100 may be mounted on the package substrate 510 via a plurality of first chip connection bumps 411. Each first chip connection bump 411 may include, for example, a solder bump.

The first integrated circuit device 100 includes a plurality of lower bump pads 181 provided in a lower surface thereof, and a plurality of first connection pads 110 provided in an upper surface thereof. Each lower bump pad 181 and each first connection pad 110 may include a conductive material, for example, copper. Each first chip connection bump 411 may be disposed between a corresponding lower bump pad 181 among the plurality of lower bump pads 181 and a corresponding substrate upper pad 513 among the plurality of substrate upper pads 513. Electrical signals (for example, an input/output data signal, a power signal, a ground signal, or the like) may be transmitted via the plurality of first chip connection bumps 411 between the first integrated circuit device 100 and the package substrate 510.

The second integrated circuit device 200 may be stacked on the first integrated circuit device 100 in an offset stack manner or a shift stack manner. A first portion of the second integrated circuit device 200 may vertically overlap the first integrated circuit device 100 and may be attached to the first integrated circuit device 100. A second portion of the second integrated circuit device 200 may not overlap vertically the first integrated circuit device 100, and protrude in the horizontal direction (for example, in X direction and/or Y direction) from one side surface of the first integrated circuit device 100. In addition, the first integrated circuit device 100 may include a first portion of the first integrated circuit device 100 vertically overlapping or covered with the second integrated circuit device 200, and a second portion of the first integrated circuit device 100 not vertically overlapping or not covered with the second integrated circuit device 200.

The second integrated circuit device 200 may be connected to the first integrated circuit device 100 without a connection medium such as a bump. In some implementations, the second integrated circuit device 200 may be bonded to the first integrated circuit device 100 in a copper-to-copper direct bonding manner or a hybrid bonding manner. The second integrated circuit device 200 includes a plurality of second connection pads 210 provided in a lower surface thereof. Some second connection pads 210 among the plurality of second connection pads 210 of the second integrated circuit device 200 may be directly connected to first connection pads 110 of the first integrated circuit device 100. Between the first integrated circuit device 100 and the second integrated circuit device 200, an electrical signal may be transmitted via the first connection pads 110 of the first integrated circuit device 100 and the second connection pads 210 of the second integrated circuit device 200.

The connection substrate 300 may be disposed between the second integrated circuit device 200 and the package substrate 510, and may be disposed on one side of the first integrated circuit device 100. The connection substrate 300 may entirely or partially overlap the second portion of the second integrated circuit device 200 in a vertical direction. The connection substrate 300 may provide an electrical signal path for transmitting an electrical signal between the second integrated circuit device 200 and the package substrate 510. The connection substrate 300 may be mounted on the package substrate 510. For example, the connection substrate 300 may be mounted on the package substrate 510 via a plurality of second chip connection bumps 413. Each second chip connection bump 413 may include, for example, a solder bump.

The connection substrate 300 includes an insulating base layer 310 and a plurality of through electrodes 320 provided in the insulating base layer 310.

The insulating base layer 310 may include a mold-based base layer. The insulating base layer 310 may include, for example, a resin layer such as an epoxy resin, and an organic filler and/or an inorganic filler contained in the resin layer. For example, the insulating base layer 310 may be formed of an epoxy mold compound (EMC).

Each of the plurality of through electrodes 320 may extend from a lower surface to an upper surface of the insulating base layer 310 to penetrate the insulating base layer 310. Each of the plurality of through electrodes 320 may include a mold through electrode vertically penetrating the mold-based base layer. Each through electrode 320 may include a conductive material, for example, copper. In some implementations, a lower surface of each through electrode 320 may be coplanar with the lower surface of the insulating base layer 310, and a lower surface of each through electrode 320 may be coplanar with the upper surface of the insulating base layer 310. The lower surface of each through electrode 320 may be connected to a corresponding second chip connection bump 413 among the second chip connection bumps 413, and the upper surface of each through electrode 320 may be connected to a corresponding second connection pad 210 among the second connection pads 210 of the second integrated circuit device 200. Each through electrode 320 may be electrically connected to a corresponding substrate upper pad 513 among the plurality of substrate upper pads 513 via a corresponding second chip connection bump 413 among the plurality of second chip connection bumps 413. Between the second integrated circuit device 200 and the package substrate 510, electrical signals (for example, an input/output data signal, a power signal, a ground signal, or the like) may be transmitted via the plurality of through electrodes 320 and the plurality of second chip connection bumps 413. The plurality of through electrodes 320 may include a structure for electrical connection between the package substrate 510 and the second integrated circuit device 200, and in the disclosure, the plurality of through electrodes 320 may be referred to as a first conductive connection structure.

In some implementations, the first integrated circuit device 100 may include a PIC device, to which at least one optical fiber OF is connected, and the second integrated circuit device 200 may include an EIC device. The PIC device may include, for example, a light source, a photonic waveguide, a filter, a coupler, etc. The PIC device may be configured to transceive an optical signal to and from an external device via the optical fiber OF, and may be configured to convert an electrical signal provided by the EIC device into an optical signal. Between the PIC device and the external device, various signals (for example, an input/output data signal, a power signal, a ground signal, or the like) may be transmitted via the optical fiber OF. The EIC device may be configured to convert an optical signal provided by the PIC device into an electrical signal. Because the semiconductor package 10 includes a CPO package, in which a PIC device and an EIC device are packaged together, a high speed of data signal processing may be achieved at low power.

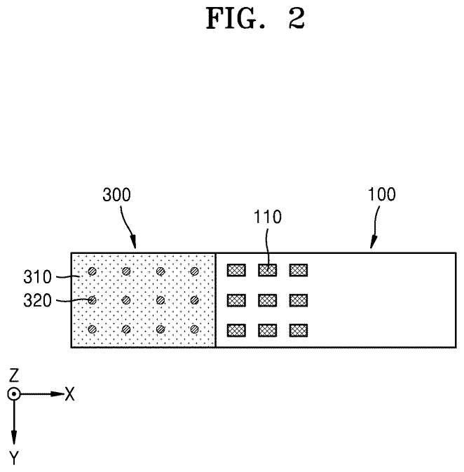

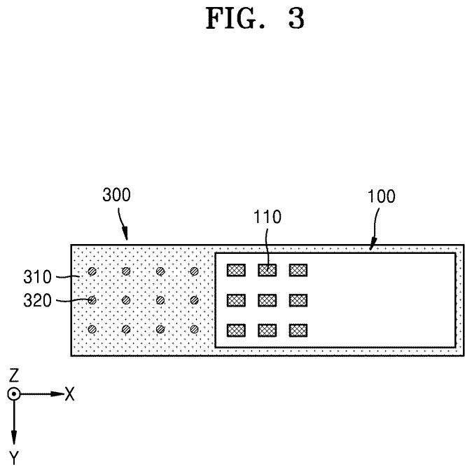

FIGS. 2 and 3 are plan views of the first integrated circuit device 100 and the connection substrate 300 of the semiconductor package 10, according to some implementations, respectively.

Referring to FIG. 2, the insulating base layer 310 of the connection substrate 300 may directly contact one side surface of the first integrated circuit device 100, and may continuously extend along the one side surface of the first integrated circuit device 100. In some implementations, the connection substrate 300 may also be apart from the first integrated circuit device 100 in the horizontal direction (for example, in X direction and/or Y direction).

Referring to FIG. 3, the insulating base layer 310 of the connection substrate 300 may extend along the side surfaces of the first integrated circuit device 100, and may surround the first integrated circuit device 100. Because the side surfaces of the first integrated circuit device 100 are covered by the insulating base layer 310 of the connection substrate 300, the side surfaces of the first integrated circuit device 100 may not be exposed to the outside.

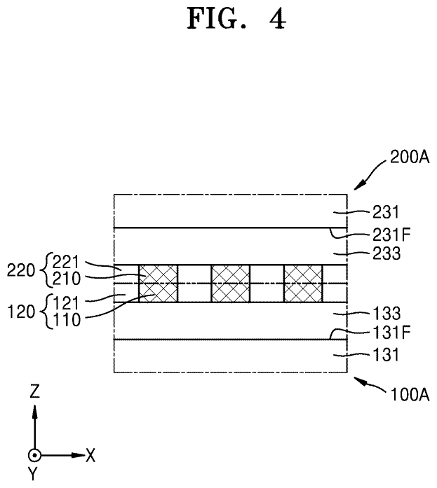

FIG. 4 is an enlarged diagram of a junction region between a first integrated circuit device 100A and a second integrated circuit device 200A in the semiconductor package 10, according to some implementations. Hereinafter, descriptions given above are omitted or simplified.

Referring to FIG. 4, the first integrated circuit device 100A includes a first semiconductor substrate 131, a first semiconductor device layer 133, and a first bonding layer 120.

The first semiconductor substrate 131 may include silicon, for example, crystalline silicon, polycrystalline silicon, or amorphous silicon. The semiconductor substrate 131 includes an active surface 131F and an inactive surface, which are opposite to each other. The active surface 131F of the first semiconductor substrate 131 may correspond to an upper surface of the first semiconductor substrate 131.

The first semiconductor device layer 133 may be disposed on the active surface 131F of the first semiconductor substrate 131. The first semiconductor device layer 133 may include a first front end of line (FEOL) structure formed on the active surface 131F of the first semiconductor substrate 131 and a first back end of line (BEOL) structure formed on the first FEOL structure. The first FEOL structure may include first individual devices formed in the first semiconductor substrate 131 and/or on the active surface 131F of the first semiconductor substrate 131. The first BEOL structure may include a distribution layer having a multilayer structure.

The first bonding layer 120 may be disposed on the first semiconductor device layer 133. The first bonding layer 120 includes the plurality of first connection pads 110 and a first pad insulating layer 121 surrounding each of the plurality of first connection pads 110.

The first pad insulating layer 121 may include an oxide and/or a nitride. For example, the first pad insulating layer 121 may include at least one material of SiO, SiN, SiCN, SiCO, and a polymer material. An upper surface of the first pad insulating layer 121 may constitute an upper surface of the first integrated circuit device 100A.

The plurality of first connection pads 110 may be disposed at substantially the same vertical level as each other. Upper surfaces of the plurality of first connection pads 110 may constitute the upper surface of the first integrated circuit device 100A. Each first connection pad 110 may include a metal material, such as copper (Cu), aluminum (Al), tungsten (W), silver (Ag), or gold (Au).

The second integrated circuit device 200A includes a second semiconductor substrate 231, a second semiconductor device layer 233, and a second bonding layer 220.

The second semiconductor substrate 231 includes an active surface 231F and an inactive surface opposite thereto. The active surface 231F of the second semiconductor substrate 231 may correspond to a lower surface of the second semiconductor substrate 231. A material of the second semiconductor substrate 231 may be the same as or similar to a material of the first semiconductor substrate 131.

The second semiconductor device layer 233 may be disposed under the active surface 231F of the second semiconductor substrate 231. The second semiconductor device layer 233 may include a second FEOL structure formed under the active surface 231F of the second semiconductor substrate 231, and a second BEOL structure formed under the second FEOL structure. The second FEOL structure may include second individual devices formed in the second semiconductor substrate 231 and/or on the active surface 231F of the second semiconductor substrate 231. The second BEOL structure may include a distribution layer having a multilayer structure.

The second bonding layer 220 may be disposed under the second semiconductor device layer 233, and may directly contact the first bonding layer 120 of the first integrated circuit device 100A. The second bonding layer 220 includes the plurality of second connection pads 210, and a second pad insulating layer 221 surrounding each of the plurality of second connection pads 210.

The second pad insulating layer 221 may include an oxide and/or a nitride. For example, the second pad insulating layer 221 may include at least one material of SiO, SiN, SiCN, SiCO, and a polymer material. A lower surface of the second pad insulating layer 221 may constitute a lower surface of the second integrated circuit device 200A.

The plurality of second connection pads 210 may be disposed at substantially the same vertical level as each other. Lower surfaces of a plurality of second connection pads 210 may constitute a lower surface of the second integrated circuit device 200A. Each second connection pad 210 may include a metal material, such as copper (Cu), aluminum (Al), tungsten (W), silver (Ag), or gold (Au).

The first integrated circuit device 100A may be bonded to the second integrated circuit device 200A by using a hybrid bonding process. The upper surface of the first pad insulating layer 121 and the lower surface of the second pad insulating layer 221 may be bonded to each other, and the upper surfaces of the plurality of first connection pads 110 may be respectively bonded to the lower surfaces of the plurality of second connection pads 210. In some implementations, a material of the first pad insulating layer 121 may be the same as a material of the second pad insulating layer 221. For example, the first pad insulating layer 121 and the second pad insulating layer 221 may include silicon oxide. In some implementations, a silicon oxide layer of the first pad insulating layer 121 may directly contact a silicon oxide layer of the second pad insulating layer 221. For bonding between the first integrated circuit device 100A and the second integrated circuit device 200A, the upper surface of the first pad insulating layer 121 and the second pad insulating layer 221 may have a bond force suitable for bonding by using a plasma process and/or a wet processing. The plurality of first connection pads 110 and the plurality of second connection pads 210 may include the same metal, for example, copper.

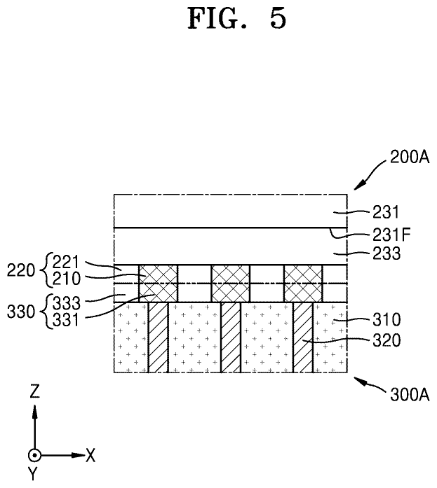

FIG. 5 is an enlarged view of a bonding region between a connection substrate 300A and the second integrated circuit device 200A in the semiconductor package 10, according to some implementations. Hereinafter, descriptions given above are omitted or simplified.

Referring to FIG. 5, the connection substrate 300A includes a third bonding layer 330 provided on the insulating base layer 310. The third bonding layer 330 includes a plurality of third connection pads 331 and a third pad insulating layer 333 surrounding each of the plurality of third connection pads 331.

The third pad insulating layer 333 may include an oxide and/or a nitride. For example, the third pad insulating layer 333 may include at least one material of SiO, SiN, SiCN, SiCO, and a polymer material. An upper surface of the third pad insulating layer 333 may constitute an upper surface of a third integrated circuit device 400.

The plurality of third connection pads 331 may be at the same vertical level as each other. Each third connection pad 331 may be connected to the through electrode 320. Upper surfaces of the plurality of third connection pads 331 may constitute an upper surface of the third integrated circuit device 400. Each third connection pad 331 may include a metal material, such as Cu, Al, W, Ag, or Au.

The connection substrate 300A may be bonded to the second integrated circuit device 200A by using a hybrid bonding. The upper surface of the third pad insulating layer 333 and the lower surface of the second pad insulating layer 221 may be bonded to each other, and the upper surfaces of the plurality of third connection pads 331 may be respectively bonded to the lower surfaces of the plurality of second connection pads 210. In some implementations, a material of the third pad insulating layer 333 may be the same as a material of the second pad insulating layer 221. For example, the third pad insulating layer 333 and the third pad insulating layer 333 may include silicon oxide. In some implementations, a silicon oxide layer of the third pad insulating layer 333 may directly contact a silicon oxide layer of the second pad insulating layer 221. For bonding between the connection substrate 300A and the second integrated circuit device 200A, the upper surface of the third pad insulating layer 333 and the lower surface of the second pad insulating layer 221 may have a bonding force suitable for bonding by using a plasma treatment and/or wet treatment process. The plurality of third connection pads 331 and the plurality of second connection pads 210 may include the same metal, for example, copper.

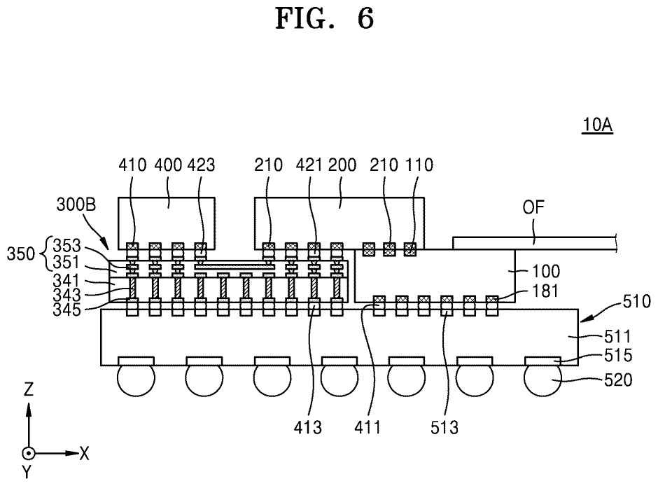

FIG. 6 is a cross-sectional view of a semiconductor package 10A according to some implementations. Hereinafter, the semiconductor package 10A illustrated in FIG. 6 is described, focusing on the difference from the semiconductor package 10 described with reference to FIG. 1.

Referring to FIG. 6, the semiconductor package 10A includes the package substrate 510, the first integrated circuit device 100, the second integrated circuit device 200, a connection substrate 300B, and the third integrated circuit device 400.

The second integrated circuit device 200 and the third integrated circuit device 400 may be mounted on the connection substrate 300B, and may be apart from each other in the horizontal direction (for example, in X direction and/or Y direction) on the connection substrate 300B. The second integrated circuit device 200 may be mounted on the connection substrate 300B via third chip connection bumps 421, and the third integrated circuit device 400 may be mounted on the connection substrate 300B via fourth chip connection bumps 423 attached to pads 410 on a lower surface thereof. The second integrated circuit device 200 and the third integrated circuit device 400 may be electrically connected to each other via the connection substrate 300B. The third integrated circuit device 400 may include an application-specific integrated circuit (ASIC) device, a memory device, a logic device, and/or a server. In the disclosure, the connection substrate 300B may also be referred to as an interposer.

The connection substrate 300B includes a base layer 341, a plurality of through electrodes 343, a lower conductive pad 345, and a redistribution structure 350.

The base layer 341 may include a silicon-based base layer. The base layer 341 may include silicon (Si), for example, crystalline silicon, polycrystalline silicon, or amorphous silicon. The base layer 341 may generally have a flat plate shape, and a lower surface and a lower surface which are opposite to each other.

The redistribution structure 350 may be disposed on the upper surface of the base layer 341. The redistribution structure 350 includes a redistribution insulating layer 351 covering the upper surface of the base layer 341 and conductive redistribution patterns 353 covered by the redistribution insulating layer 351.

In some implementations, the redistribution insulating layer 351 may include an organic insulating material. For example, the redistribution insulating layer 351 may include a photo imageable dielectric (PID) such as polyimide. In some implementations, the redistribution insulating layer 351 may include an inorganic insulating material. For example, the redistribution insulating layer 351 may include at least one of silicon oxide and silicon nitride.

The conductive redistribution patterns 353 may include a plurality of conductive layers at different levels in the redistribution insulating layer 351 to form a multilayer structure, and conductive vias extending in the vertical direction (Z direction) within the redistribution insulating layer 351 to connect the plurality of conductive layers. For example, the conductive redistribution patterns 353 may include at least one metal of W, Al, and Cu. The conductive redistribution patterns 353 may include pads, to which a plurality of third chip connection bumps 421 are attached, and pads to which a plurality of fourth chip connection bumps 423 are attached. In addition, the conductive redistribution patterns 353 may include a second conductive connection structure configured to transmit an electrical signal between the second integrated circuit device 200 and the third integrated circuit device 400.

The lower conductive pad 345 may be disposed on a lower surface of the base layer 341. The lower conductive pad 345 may be connected to the substrate upper pad 513 of the package substrate 510 via the second chip connection bump 413. The lower conductive pad 345 may include at least one metal of W, Al, and Cu.

The plurality of through electrodes 343 may be configured to electrically connect between the conductive redistribution patterns 353 of the redistribution structure 350 and lower conductive pads 345. Each through electrode 343 may extend from the upper surface to the lower surface of the base layer 341, and penetrate the base layer 341 in the vertical direction (Z direction). An upper end of each through electrode 343 may be connected to the conductive redistribution patterns 353 of the redistribution structure 350, and a lower end of each through electrode 343 may be connected to the lower conductive pad 345 corresponding thereto.

For example, each through electrode 343 may include a conductive plug of a column shape, which penetrates the base layer 341, and a conductive barrier layer of a cylinder shape surrounding a sidewall of the conductive plug. A via insulating layer may be disposed between the base layer 341 and each through electrode 343. The via insulating layer may include an oxide layer, a nitride layer, a carbide layer, a polymer, or a combination thereof. At least one of the plurality of through electrodes 343 may constitute the first conductive connection structure, which electrically connects between the package substrate 510 and the second integrated circuit device 200 together with the conductive redistribution patterns 353. In addition, at least one through electrode 343 among the plurality of through electrodes 343 may electrically connect the third integrated circuit device 400 to the package substrate 510 together with the conductive redistribution patterns 353.

In some implementations, the first integrated circuit device 100 may include a PIC device, to which at least one optical fiber OF is connected, and the second integrated circuit device 200 may include an EIC device. In some implementations, the second integrated circuit device 200 may include a PIC device, to which at least one optical fiber OF is connected, and the first integrated circuit device 100 may include an EIC device.

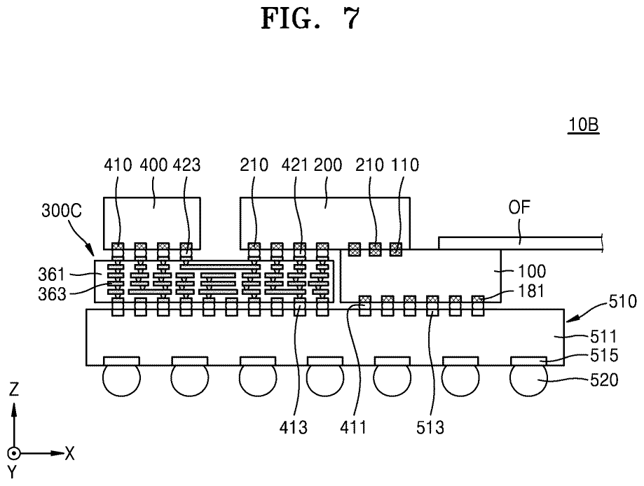

FIG. 7 is a cross-sectional view of a semiconductor package 10B according to some implementations. Hereinafter, the semiconductor package 10B illustrated in FIG. 7 is described, focusing on the difference from the semiconductor package 10A described with reference to FIG. 6.

Referring to FIG. 7, in the semiconductor package 10B, the second integrated circuit device 200 and the third integrated circuit device 400 may be mounted on a connection substrate 300C, and may be electrically connected to each other via the connection substrate 300C. The connection substrate 300C includes an insulating base layer 361 and conductive distribution patterns 363 provided in the insulating base layer 361. In some implementations, the connection substrate 300C may include a passive device such as a capacitor. In the disclosure, the connection substrate 300C may be referred to as a redistribution interposer.

The insulating base layer 361 may include an organic-based base layer. The insulating base layer 361 may include a plurality of insulating layers vertically stacked. The insulating base layer 361 may include a PID such as polyimide.

The conductive distribution patterns 363 may include a plurality of conductive layers at different levels in the insulating base layer 361 to form a multilayer structure, and conductive vias extending in the vertical direction (Z direction) in the insulating base layer 361 to connect the plurality of conductive layers to each other. For example, the conductive distribution patterns 363 may include at least one metal of W, Al, and Cu.

The conductive distribution patterns 363 may include a first conductive connection structure electrically connecting between the second integrated circuit device 200 and the package substrate 510, a second conductive connection structure electrically connecting between the second integrated circuit device 200 and the third integrated circuit device 400, a third conductive connection structure electrically connecting between the third integrated circuit device 400 and the package substrate 510, pads to which the plurality of third chip connection bumps 421 are attached, pads to which the plurality of fourth chip connection bumps 423 are attached, and pads to which the plurality of second chip connection bumps 413 are attached.

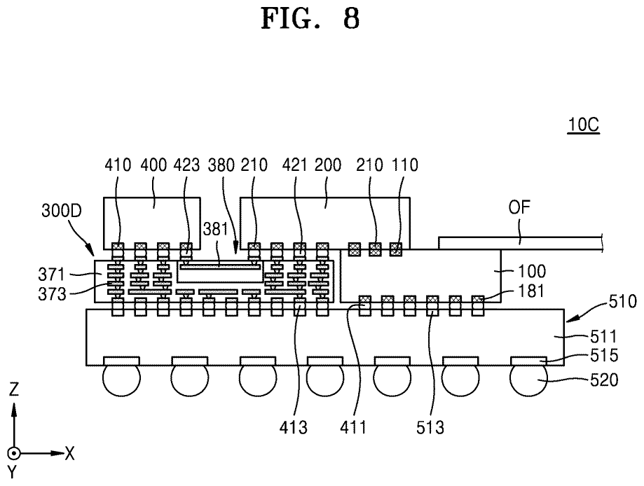

FIG. 8 is a cross-sectional view of a semiconductor package 10C according to some implementations. Hereinafter, the semiconductor package 10C illustrated in FIG. 8 is described, focusing on the difference from the semiconductor package 10A described with reference to FIG. 6.

Referring to FIG. 8, in the semiconductor package 10C, the second integrated circuit device 200 and the third integrated circuit device 400 may be mounted on a connection substrate 300D, and may be electrically connected to each other via the connection substrate 300D. The connection substrate 300D includes an insulating base layer 371, a conductive distribution pattern 373 disposed in the insulating base layer 371, and a bridge chip 380 disposed in the insulating base layer 371. In some implementations, the connection substrate 300D may include a passive device such as a capacitor.

The insulating base layer 371 may include an organic insulating material and/or an inorganic insulating material. The conductive distribution pattern 373 may include a plurality of conductive layers at different levels in the insulating base layer 371 to form a multilayer structure, and may include conductive vias extending in the vertical direction (Z direction) in the insulating base layer 371 to connect the plurality of conductive layers to each other. For example, the conductive distribution pattern 373 may include at least one metal of W, Al, and Cu. The conductive distribution pattern 373 may include the first conductive connection structure electrically connecting between the second integrated circuit device 200 and the package substrate 510, a third conductive connection structure electrically connecting between the third integrated circuit device 400 and the package substrate 510, pads to which the plurality of fourth chip connection bumps 423 are attached, and pads to which the plurality of second chip connection bumps 413 are attached.

The bridge chip 380 may be accommodated in a recess of the insulating base layer 371. The bridge chip 380 includes a bridge distribution pattern 381 configured to electrically connect between the second integrated circuit device 200 and the third integrated circuit device 400. In the disclosure, the bridge distribution pattern 381 of the bridge chip 380 may be referred to as the second conductive connection structure.

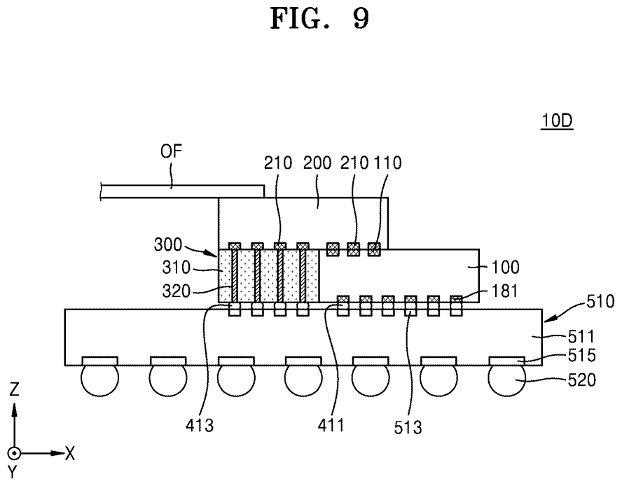

FIG. 9 is a cross-sectional view of a semiconductor package 10D according to some implementations. Hereinafter, the semiconductor package 10D illustrated in FIG. 9 is described, focusing on the difference from the semiconductor package 10 described with reference to FIG. 1.

Referring to FIG. 9, in the semiconductor package 10D, the first integrated circuit device 100 may include an EIC device, and the second integrated circuit device 200 may include a PIC device. The optical fiber OF may be connected to the second integrated circuit device 200. The second integrated circuit device 200 may be configured to transceive various signals to and from an external device via the optical fiber OF, and may be configured to transceive signals to and from the package substrate 510 via the connection substrate 300. The first integrated circuit device 100 may be bonded to the second integrated circuit device 200 by using a copper-to-copper direct bonding or hybrid bonding, and may be configured to convert the optical signal transmitted by the second integrated circuit device 200 into an electrical signal.

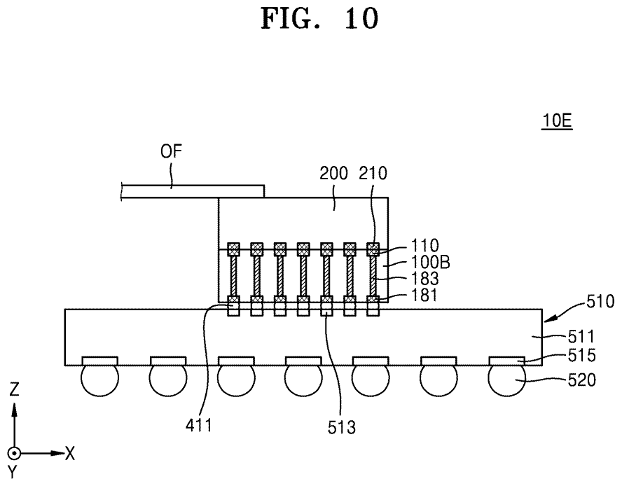

FIG. 10 is a cross-sectional view of a semiconductor package 10E according to some implementations. Hereinafter, the semiconductor package 10E illustrated in FIG. 10 is described, focusing on the difference from the semiconductor package 10D described with reference to FIG. 9.

Referring to FIG. 10, in the semiconductor package 10E, a first integrated circuit device 100B may include an EIC device, and the second integrated circuit device 200 may include a PIC device. The first integrated circuit device 100B includes a plurality of through electrodes 183. Each through electrode 183 may have a pillar shape extending in the vertical direction (Z direction) in the first integrated circuit device 100B. Each through electrode 183 may vertically penetrate at least one first semiconductor substrate (refer to 131 in FIG. 4) of the first integrated circuit device 100B. Each through electrode 183 may electrically connect between the corresponding lower bump pad 181 among the plurality of lower bump pads 181 and the corresponding first connection pad 110 among the plurality of first connection pads 110. The second integrated circuit device 200 may be electrically connected to the package substrate 510 and/or the first integrated circuit device 100B via the plurality of through electrodes 183. In addition, the first individual devices provided in the first integrated circuit device 100B may be electrically connected to the package substrate 510 via the plurality of through electrodes 183.

The first integrated circuit device 100B and the second integrated circuit device 200 may be bonded to each other by using a hybrid bonding manner. Similar to the descriptions given with reference to FIG. 4, each first connection pad 110 may be directly connected to a second connection pad 210. In addition, similar to the descriptions given with reference to FIG. 4, the first integrated circuit device 100B may include a first pad insulating layer surrounding the plurality of first connection pads 110, the second integrated circuit device 200 may include a second pad insulating layer surrounding the plurality of second connection pads 210, and the first pad insulating layer of the first integrated circuit device 100B may be directly connected to the second pad insulating layer of the second integrated circuit device 200.

As illustrated in FIG. 10, a horizontal width of the first integrated circuit device 100B may be the same as a horizontal width of the second integrated circuit device 200. In some implementations, the horizontal width of the first integrated circuit device 100B may be greater than the horizontal width of the second integrated circuit device 200, and a portion of the first integrated circuit device 100B may not be covered by the second integrated circuit device 200. In some implementations, the horizontal width of the first integrated circuit device 100B may be less than the horizontal width of the second integrated circuit device 200, and a portion of the second integrated circuit device 200 may not vertically overlap the first integrated circuit device 100B.

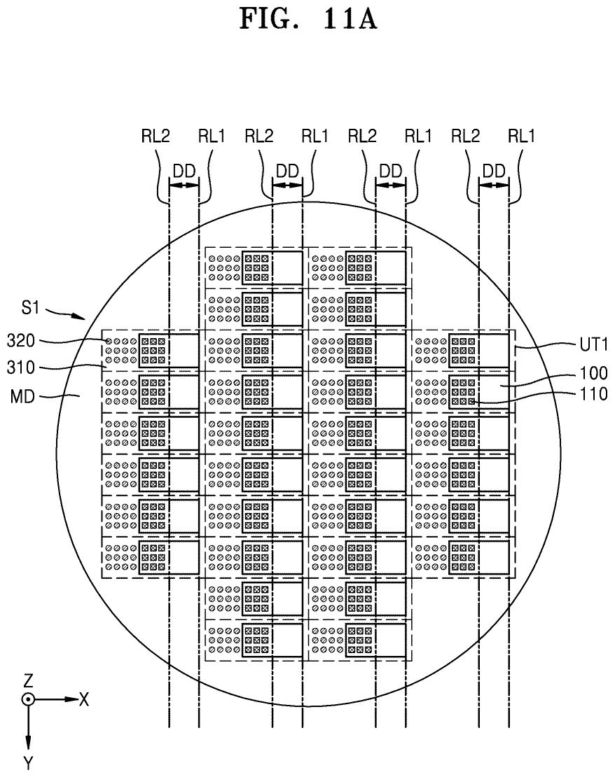

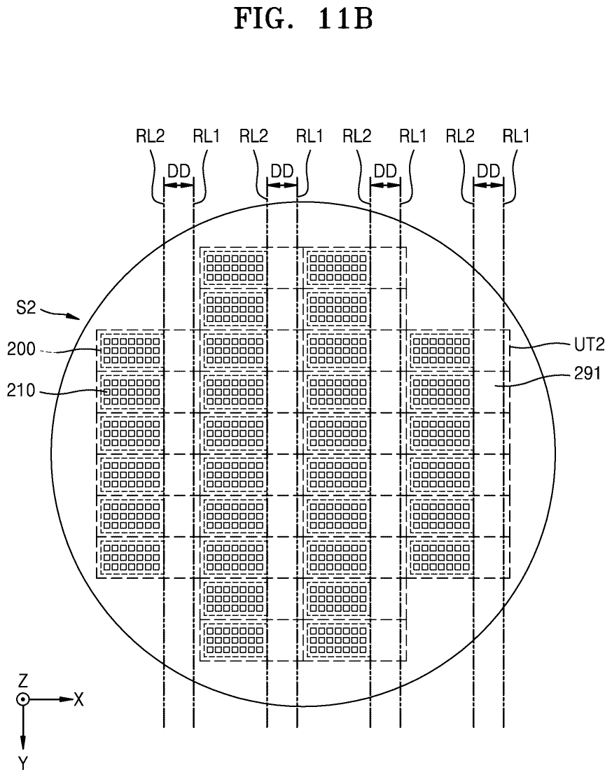

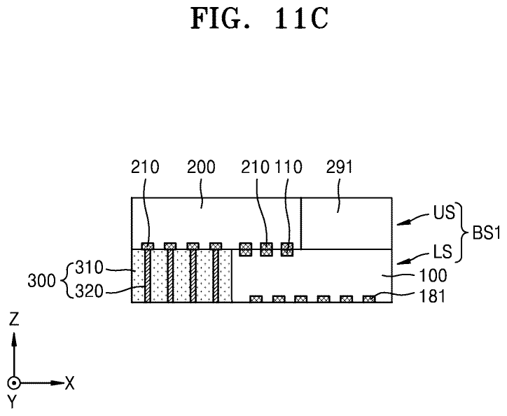

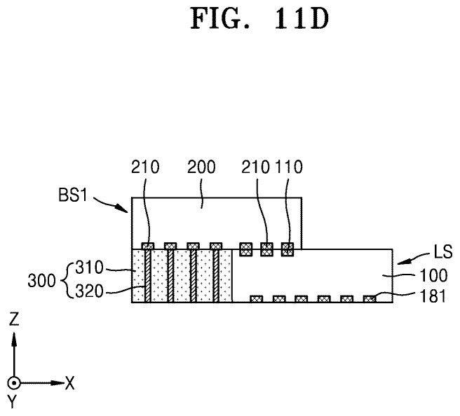

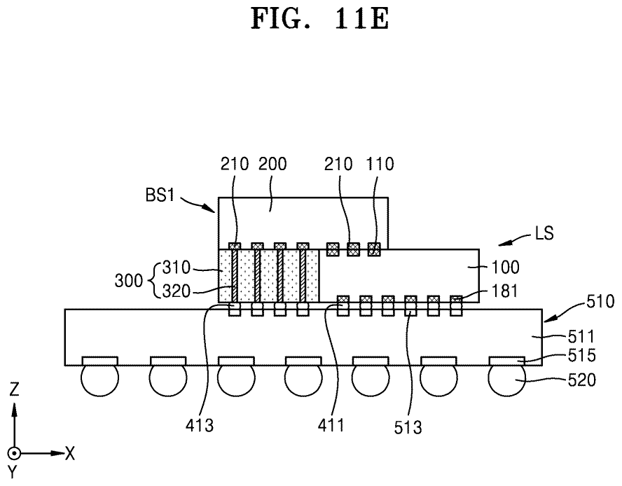

FIGS. 11A through 11E are diagrams for explaining a method of manufacturing the semiconductor package 10, according to some implementations. Hereinafter, a method of manufacturing the semiconductor package 10 illustrated in FIG. 1 is described with reference to FIGS. 11A through 11E.

FIG. 11A is a plan view of a first structure S1 including a plurality of first integrated circuit devices 100, and FIG. 11B is a plan view of a second structure S2 including a plurality of second integrated circuit devices 200.

Referring to FIGS. 11A and 11B, a method of manufacturing the semiconductor package 10 may include preparation of the first structure S1 and the second structure S2, respectively.

Referring to FIG. 11A, the first structure S1 may surround the plurality of first integrated circuit devices 100, the plurality of through electrodes 320, and a molding layer MD. The molding layer MD may surround the plurality of first integrated circuit devices 100 and the plurality of through electrodes 320. In the first structure S1, each of the plurality of first integrated circuit devices 100 may be aligned with any one of first reference lines RL1 in parallel with a second horizontal direction (for example, Y direction). For example, one edge of each of the first integrated circuit devices 100 may be aligned with any one of the first reference lines RL1.

Forming the first structure S1 may include arranging the plurality of first integrated circuit devices 100 on a carrier substrate, forming the plurality of through electrodes 320 on the carrier substrate, and forming the molding layer MD surrounding the plurality of first integrated circuit devices 100 and the plurality of through electrodes 320 on the carrier substrate. The molding layer MD may be formed from, for example, an EMC. The first structure S1 may be referred to as a reconfiguration structure.

The first structure S1 includes a plurality of first unit regions UTI arranged in a first horizontal direction (for example, X direction) and the second horizontal direction (for example, Y direction). The plurality of first unit regions UTI may be separated from each other by using a cutting process to follow. Each first unit region UTI includes one first integrated circuit device 100, the plurality of through electrodes 320, and the insulating base layer 310 surrounding one first integrated circuit device 100 and the plurality of through electrodes 320. The insulating base layer 310 includes a portion of the molding layer MD.

Referring to FIG. 11B, the second structure S2 includes the plurality of second integrated circuit devices 200 formed on a substrate such as a wafer. In the second structure S2, each of the plurality of second integrated circuit devices 200 may be aligned in any one of second reference lines RL2 in parallel with the second horizontal direction (for example, Y direction). For example, one edge of each second integrated circuit device 200 may be aligned with any one of the second reference lines RL2. Each second reference line RL2 may be apart from one of the first reference lines RL1 defined with respect to the first structure S1 by a constant offset distance DD in the first horizontal direction (for example, X direction).

The second structure S2 includes a plurality of second unit regions UT2 arranged in the first horizontal direction (for example, X direction) and the second horizontal direction (for example, Y direction). The plurality of second unit regions UT2 may be separated from each other by using a cutting process to follow. Each second unit region UT2 includes one second integrated circuit device 200 and a dummy structure 291. Each second unit region UT2 and each first unit region UT1 may have the same dimensions in the horizontal direction (for example, X direction and/or Y direction).

Referring to FIG. 11C together with FIGS. 11A and 11B, the method of manufacturing the semiconductor package 10 may include forming a bonded structure BS1, in which a lower structure LS corresponding to the first unit region UT1 of the first structure S1 is bonded to an upper structure US corresponding to the second unit region UT2 of the second structure S2, from the first structure S1 and the second structure S2.

In some implementations, forming the bonded structure BS1 may include bonding the first structure S1 and the second structure S2 to each other, and separating a third structure into a plurality of bonding structures BS1, which has been generated by bonding the first structure S1 and the second structure S2 to each other, into a plurality of bonded structures BS1 by performing a cutting process on the third structure. Bonding the first structure S1 and the second structure S2 to each other may be performed, for example, by using a hybrid bonding process. When the first structure S1 and the second structure S2 are bonded to each other, the plurality of first unit regions UT1 of the first structure S1 may be aligned with and bonded to the plurality of second unit regions UT2 of the second structure S2, respectively.

Referring to FIG. 11D together with FIG. 11C, the dummy structure 291 may be removed from the upper structure US so that a portion of the upper surface of the first integrated circuit device 100 is exposed.

Referring to FIG. 11E, the bonded structure BS1 may be mounted on the package substrate 510. The bonded structure BS1 may be mounted on the package substrate 510 via the plurality of first chip connection bumps 411 and the plurality of second chip connection bumps 413.

Referring to FIGs. 1 and 11E, after the bonded structure BS1 is mounted on the package substrate 510, the optical fiber OF may be connected to the first integrated circuit device 100.

In some implementations, forming the bonded structure BS1 illustrated in FIG. 11D may include forming the plurality of second integrated circuit devices 200 from the second structure S2 by performing a cutting process on the second structure S2 in FIG. 11B, bonding the second integrated circuit device 200 to the first structure S1 in FIG. 11A, and performing a cutting process on a fourth structure generated by bonding the plurality of second integrated circuit devices 200 to the first structure S1 to separate the fourth structure into the plurality of bonded structures BS1.

In some implementations, forming the bonded structure BS1 illustrated in FIG. 11D may include separating the first structure S1 into the plurality of first unit regions UT1 by performing a cutting process on the first structure S1 in FIG. 11A, forming the plurality of second integrated circuit devices 200 from the second structure S2 by performing a cutting process on the second structure S2 in FIG. 11B, and forming the bonded structure BS1 by bonding each first unit region UT1 to each second integrated circuit device 200.

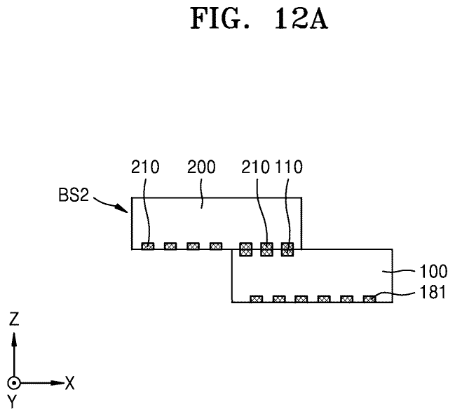

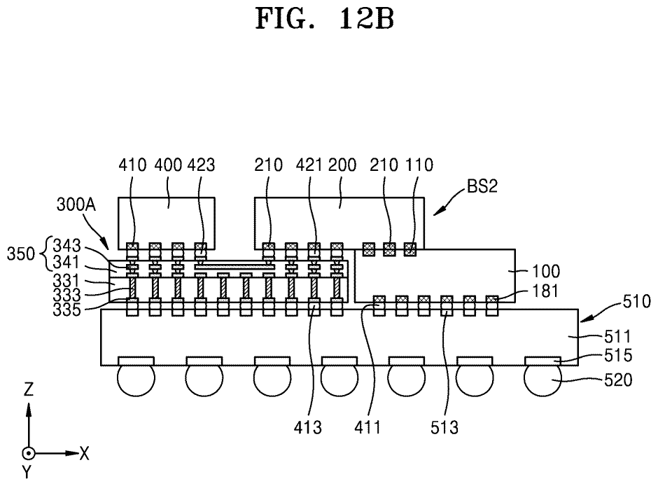

FIGS. 12A and 12B are cross-sectional views illustrating a method of manufacturing the semiconductor package 10A, according to some implementations. Hereinafter, a method of manufacturing the semiconductor package 10A illustrated in FIG. 6 is described, with reference to FIGS. 12A and 12B.

Referring to FIG. 12A, the first integrated circuit device 100 and the second integrated circuit device 200 may be prepared, and the first integrated circuit device 100 and the second integrated circuit device 200 may be bonded to each other. The first integrated circuit device 100 and the second integrated circuit device 200 may be bonded to each other by using, for example, a copper-to-copper direct bonding or hybrid bonding process.

Referring to FIG. 12B, the connection substrate 300 may be mounted on the package substrate 510, and a bonded structure BS2 in FIG. 12A may be mounted on the package substrate 510 and the connection substrate 300. The first integrated circuit device 100 of the bonded structure BS2 may be attached to the package substrate 510 via the plurality of first chip connection bumps 411, and the second integrated circuit device 200 of the bonded structure BS2 may be attached to the connection substrate 300 via the plurality of third chip connection bumps 421. Next, the third integrated circuit device 400 may be mounted on the connection substrate 300. The third integrated circuit device 400 may be attached to the connection substrate 300 via the plurality of third chip connection bumps 421.

Referring to FIG. 6, after the third integrated circuit device 400 is mounted on the connection substrate 300, the optical fiber OF may be connected to the first integrated circuit device 100.

According to some implementations of the disclosure, because a semiconductor package includes a CPO package, in which a PIC device and an EIC device are packaged together, a high speed of data signal processing may be achieved at a low power.

According to some implementations of the disclosure, because other integrated circuit devices such as ASIC devices may be packaged together with PIC devices and EIC devices by using a connection substrate, a semiconductor package, in which various types of devices are integrated in a relatively small footprint, may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the disclosure has been particularly shown and described with reference to implementations thereof, it will be understood that various changes in form and details may be made therein without departing from the spirit and scope of the following claims.

1. A semiconductor package comprising:
a package substrate;
a connection substrate mounted on the package substrate, the connection substrate including a first conductive connection structure;
a first integrated circuit device mounted on the package substrate; and
a second integrated circuit device disposed on the connection substrate and the first integrated circuit device, the second integrated circuit device including a first portion overlapping the first integrated circuit device and a second portion overlapping the connection substrate,
wherein one of the first integrated circuit device and the second integrated circuit device comprises a photonic integrated circuit device to which an optical fiber is attached, and the other of the first integrated circuit device and the second integrated circuit device comprises an electronic integrated circuit device, and
wherein the second integrated circuit device is electrically connected to the package substrate via the first conductive connection structure of the connection substrate.

2. The semiconductor package of claim 1,
wherein the first integrated circuit device comprises a plurality of first connection pads provided on an upper surface of the first integrated circuit device,
the second integrated circuit device comprises a plurality of second connection pads provided on a lower surface of the second integrated circuit device, and
the plurality of first connection pads are directly and respectively bonded to the plurality of second connection pads.

3. The semiconductor package of claim 2,
wherein the first integrated circuit device comprises a first pad insulating layer surrounding the plurality of first connection pads,
wherein the second integrated circuit device comprises a second pad insulating layer surrounding the plurality of second connection pads, and
wherein the first pad insulating layer is directly bonded to the second pad insulating layer.

4. The semiconductor package of claim 3, wherein each of the first pad insulating layer and the second pad insulating layer comprises silicon oxide.

5. The semiconductor package of claim 1,
wherein the connection substrate comprises an insulating base layer,
wherein the insulating base layer comprises a mold-based base layer,
wherein the first conductive connection structure of the connection substrate penetrates the mold-based base layer and comprises a plurality of through electrodes, and
wherein the plurality of through electrodes comprises a plurality of mold through electrodes, the plurality of mold through electrodes configured to electrically connect the second integrated circuit device and the package substrate.

6. The semiconductor package of claim 5,
wherein the first integrated circuit device comprises a plurality of first connection pads provided on an upper surface of the first integrated circuit device and a first pad insulating layer surrounding the plurality of first connection pads,
wherein the second integrated circuit device comprises a plurality of second connection pads provided on a lower surface of the second integrated circuit device and a second pad insulating layer surrounding the plurality of second connection pads,
wherein the connection substrate comprises a plurality of third connection pads respectively connected to the plurality of mold through electrodes and a third pad insulating layer surrounding the plurality of third connection pads,
wherein some second connection pads among the plurality of second connection pads are directly and respectively bonded to the plurality of first connection pads,
wherein the other second connection pads among the plurality of second connection pads are directly and respectively bonded to the plurality of third connection pads, and
wherein each of the first pad insulating layer and the third pad insulating layer is directly bonded to the second pad insulating layer.

7. The semiconductor package of claim 5, wherein the mold-based base layer is directly connected to side surfaces of the first integrated circuit device.

8. The semiconductor package of claim 7, wherein the mold-based base layer surrounds the first integrated circuit device.

9. The semiconductor package of claim 1, further comprising a third integrated circuit device mounted on the connection substrate and electrically connected to the second integrated circuit device via the connection substrate.

10. The semiconductor package of claim 9,
wherein the connection substrate comprises a silicon-based base layer, and
the first conductive connection structure of the connection substrate comprises a plurality of through electrodes penetrating the silicon-based base layer.

11. The semiconductor package of claim 9,
wherein the connection substrate comprises an insulating base layer, and the first conductive connection structure of the connection substrate comprises a plurality of redistribution patterns in the insulating base layer.

12. The semiconductor package of claim 9,
wherein the connection substrate further comprises an insulating base layer and a bridge chip in the insulating base layer, and
wherein the bridge chip comprises a bridge distribution pattern electrically connecting the second integrated circuit device to the third integrated circuit device.

13. The semiconductor package of claim 1,
wherein the first integrated circuit device comprises a photonic integrated circuit device, and the second integrated circuit device comprises an electronic integrated circuit device.

14. The semiconductor package of claim 1,
wherein the first integrated circuit device comprises an electronic integrated circuit device, and the second integrated circuit device comprises a photonic integrated circuit device.

15. A semiconductor package comprising:
a package substrate;
a connection substrate mounted on the package substrate, the connection substrate including a mold-based base layer and a plurality of mold through electrodes penetrating the mold-based base layer;
a photonic integrated circuit device mounted on the package substrate and configured to transceive optical signals via an optical fiber; and
an electronic integrated circuit device mounted on the photonic integrated circuit device and the connection substrate and configured to process a signal provided by the photonic integrated circuit device,
wherein the electronic integrated circuit device is directly connected to the photonic integrated circuit device and the connection substrate, and
the electronic integrated circuit device is electrically connected to the package substrate via the plurality of mold through electrodes.

16. The semiconductor package of claim 15,
wherein the photonic integrated circuit device comprises a plurality of first connect pads provided on an upper surface of the photonic integrated circuit device and a first pad insulating layer surrounding the plurality of first connection pads,
wherein the electronic integrated circuit device comprises a plurality of second pad insulating layers provided on a lower surface of the electronic integrated circuit device and a second pad insulating layer surrounding the plurality of second connection pads,
wherein the connection substrate comprises a plurality of third connection pads connected to the plurality of mold through electrodes and a third pad insulating layer surrounding the plurality of third connection pads,
wherein one or more second connection pads among the plurality of second connection pads are directly and respectively bonded to the plurality of first connection pads,
wherein other second connection pads different from the one or more second connection pads among the plurality of second connection pads are directly and respectively bonded to the plurality of third connection pads, and
wherein each of the first pad insulating layer and the third pad insulating layer is directly bonded to the second pad insulating layer.

17. The semiconductor package of claim 16, wherein each of the first pad insulating layer, the second pad insulating layer, and the third pad insulating layer comprises silicon oxide.

18.-19. (canceled)

20. A semiconductor package comprising:
a package substrate;
a connection substrate mounted on the package substrate;
a first integrated circuit device mounted on the package substrate;
a second integrated circuit device disposed on the connection substrate and the first integrated circuit device, wherein the second integrated circuit device is directly connected to the first integrated circuit device and electrically connected to the package substrate via the connection substrate; and
a third integrated circuit device mounted on the connection substrate and electrically connected to the second integrated circuit device via the connection substrate,
wherein one of the first integrated circuit device and the second integrated circuit device comprises a photonic integrated circuit device to which an optical fiber is attached, and the other of the first integrated circuit device and the second integrated circuit device comprises an electronic integrated circuit device.

21. The semiconductor package of claim 20,
wherein the connection substrate further comprises:
a silicon-based base layer;
a plurality of through electrodes penetrating the silicon-based base layer; and
a redistribution structure disposed on the silicon-based base layer, and the redistribution structure comprising a plurality of redistribution patterns electrically connected to the plurality of through electrodes,
wherein the second integrated circuit device is electrically connected to the package substrate via at least one of the plurality of through electrodes, and
wherein the second integrated circuit device is electrically connected to the third integrated circuit device via the plurality of redistribution patterns.

22. The semiconductor package of claim 20,
wherein the connection substrate comprises:
an insulating base layer; and
a plurality of redistribution patterns disposed in the insulating base layer,
wherein the second integrated circuit device is electrically connected to each of the package substrate and the third integrated circuit device via the redistribution patterns.

23.-25. (canceled)
